(19) United States
(12) Patent Application Publication
(10) Pub. No.: US 2014/0133121 A1
(43) Pub. Date: May 15, 2014

(54) MOUNTING APPARATUS FOR CIRCUIT BOARDS

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: ZHAN-YANG LI, Shenzhen (CN)

(73) Assignees: HON HAI PRECISION INDUSTRY CO., LTD., New Taipei (TW); HONG FU JIN PRECISION INDUSTRY (ShenZhen) CO., LTD., New Taipei (TW)

(21) Appl. No.: 13/972,196

(22) Filed: Aug. 21, 2013

(30) Foreign Application Priority Data
Nov. 9, 2012 (CN) 2012104461794

(51) Int. Cl. H05K 7/00

(52) U.S. Cl. CPC H05K 7/00
USPC 361/784

(57) ABSTRACT

A mounting apparatus for fixing circuit boards includes a position member configured to mount first circuit board, and a switch member configured to mount a second circuit board. The position member includes a first positioning hole. The switch member includes an enclosure and a rotating axle rotatably mounted in the enclosure. A spring is positioned on the rotating axle. A first engaging portion and a second engaging portion extend from the rotating axle. Two second supporting portions are located in the enclosure. The rotating axle resists against the spring and compresses the spring. The second engaging portion passes through the first positioning hole and resists against the position member. The second circuit board is attached to the first circuit board by the first engaging portion resisting against the two second supporting portions.

### BACKGROUND

1. Technical Field

The present disclosure relates to a mounting apparatus for circuit boards.

2. Description of Related Art

A typical mounting apparatus may include a screw and a screw nut. A screw includes a head portion and a shaft. The screw nut defines an installation hole. A bottom panel defines a through hole. A circuit board defines a screw hole. In use, the shaft is inserted through the through hole, the screw hole, and the installation hole to secure the circuit board to the bottom panel. Users need to manually disengage the screw and the screw nut with a tool to remove the circuit board from the bottom panel, which process may be laborious and inefficient.

Therefore, there is a need for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric, exploded view of an embodiment of a mounting apparatus for a circuit board; the mounting apparatus includes a first circuit board, a second circuit board, and a switch member.

FIG. 2 is an isometric view of an enclosure of the switch member of FIG. 1.

FIG. 3 is an isometric view of an enclosure of the switch member of FIG. 1, viewed from another aspect.

FIG. 4 is an assembled view of the second circuit board and the switch member of FIG. 1.

FIG. 5 is an assembled view of the first circuit board, the second circuit board, and the switch member of FIG. 1.

FIG. 6 is a cross-sectional view of the mounting apparatus for a circuit board of FIG. 5, taken along line VI-VI.

FIG. 7 is a cross-sectional view of the mounting apparatus for a circuit board of FIG. 6, shown in another state.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

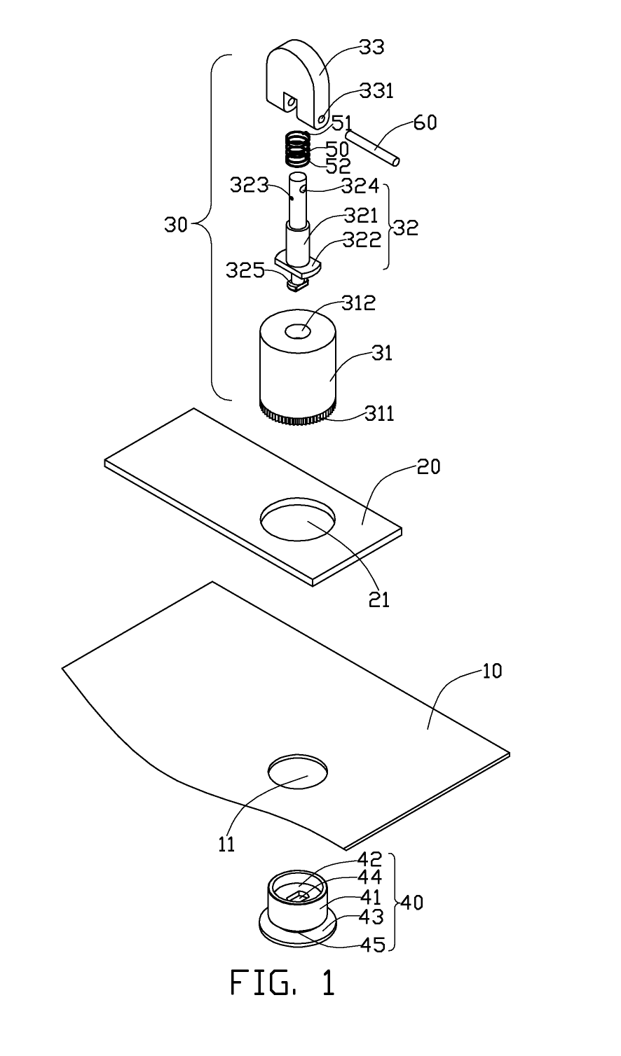

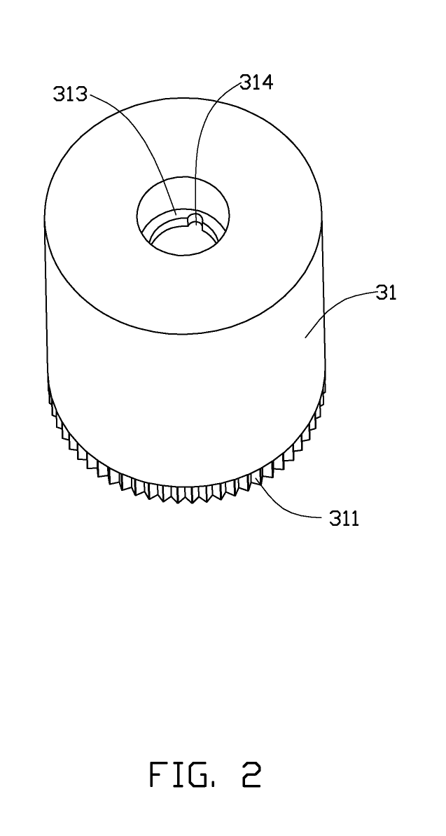

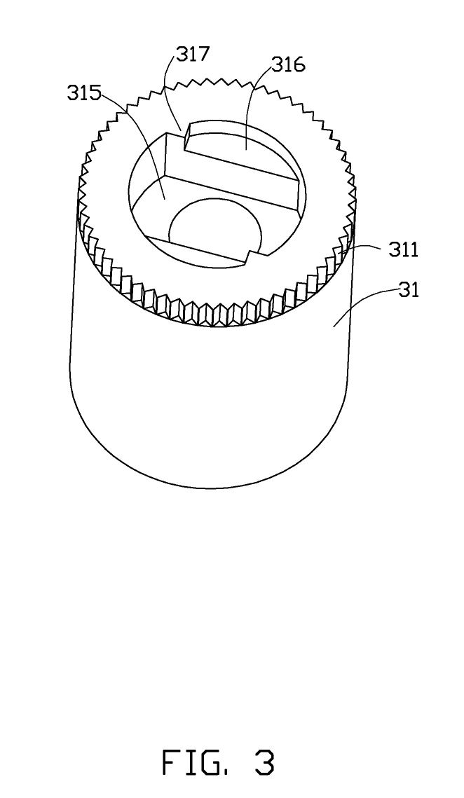

FIGS. 1 to 3 show a mounting apparatus for a circuit board. It includes a first circuit board 10, a second circuit board 20, and a switch member 30. The switch member 30 is connected to the first circuit board 10 and the second circuit board 20.

A first mounting hole 11 is defined in the first circuit board 10. A position member 40 is received in the first mounting hole 11. The position member 40 includes a column-shaped sidewall 41, a top wall 42, and a bottom wall 43 horizontally extending from a bottom edge of the sidewall 41. A bar-shaped first positioning hole 44 is defined in the top wall 42. A mounting groove 45 is defined between the sidewall 41 and the bottom wall 43. In one embodiment, a diameter of the sidewall 41 is slightly greater than a diameter of the first mounting hole 11. A width of the mounting groove 45 is equal to a thickness of the first circuit board 10.

A second mounting hole 21 is defined in the second circuit board 20. The switch member 30 is received in the second mounting hole 21. The switch member 30 includes a column-shaped enclosure 31, a rotating axle 32 rotatably mounted in the enclosure 31, and a handle 33 mounted on a top of the rotating axle 32. A plurality of protrusion ribs 311 are formed on a bottom edge of the enclosure 31. A first through hole 312 is defined in the enclosure 31. An annular first supporting portion 313 extends from an inside surface of the enclosure 31. An arc-shaped position slot 314 is defined in the first supporting portion 313. A cutout 315 is defined in a bottom of the enclosure 31. An arc-shaped second supporting portion 316 is located on each of the two sides of the first through hole 312 in the cutout 315. A resisting portion 317 is located on one side of each second supporting portion 316. In one embodiment, a diameter of the enclosure 31 is slightly greater than a diameter of the second mounting hole 21.

The rotating axle 32 includes an operating portion 321. A first engaging portion 322 perpendicularly extends from opposite sides of the operating portion 321. A second positioning hole 323 and a fixing hole 324 are defined in the operating portion 321. A second engaging portion 325 horizontally extends from a bottom of the operating portion 321. A spring 50 is positioned on the operating portion 321. The spring 50 includes a first distal end 51 and a second distal end 52. A second through hole 331 is defined in each of the two sides of the handle 33. The handle 33 is mounted to the operating portion 321 by a fastener 60. In one embodiment, the first engaging portion 322 is perpendicular to the second engaging portion 325. A length of the first engaging portion 322 is greater than a diameter of the first through hole 312.

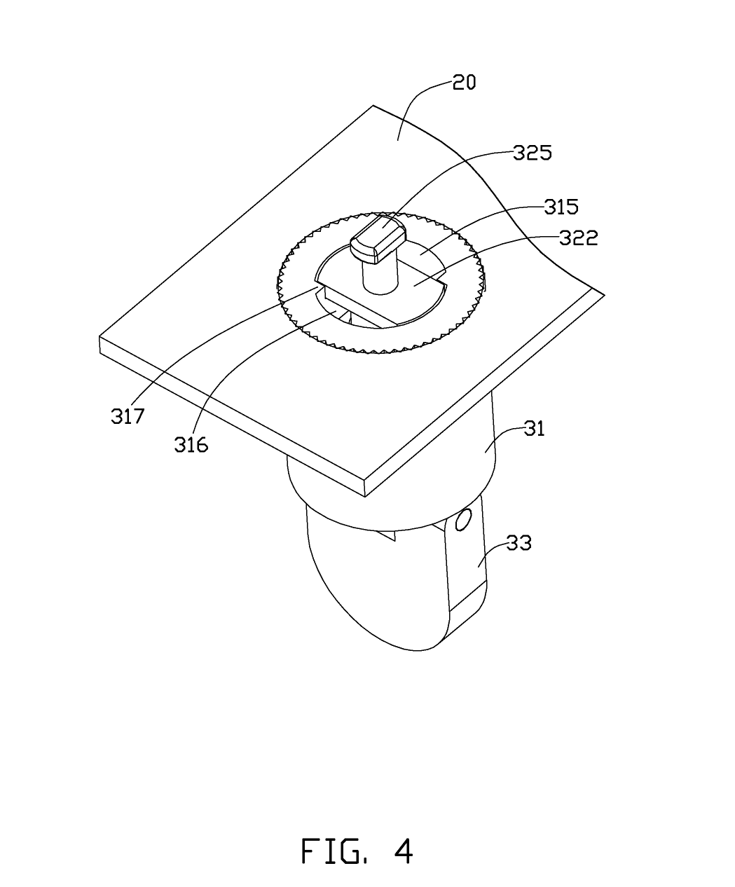

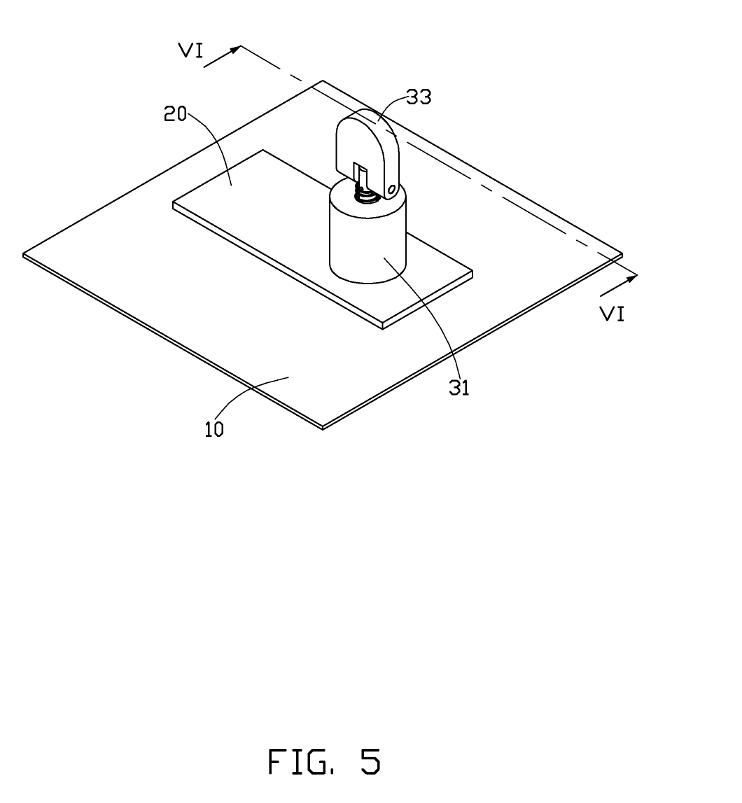

FIGS. 1 to 5 show that in assembly, the position member 40 is located in the first mounting hole 11 of the first circuit board 10. An inner surface of the first mounting hole 11 is received in the mounting groove 45 of the position member 40. Therefore, the position member 40 is mounted on the first circuit board 10. The operating portion 321 of the rotating axle 32 extends through the first through hole 312 from the bottom of the enclosure 31. The first engaging portion 322 is received in the cutout 315. The spring 50 is placed on the operating portion 321 near a top of the enclosure 31. The first distal end 51 of the spring 50 is received in the second positioning hole 323. The second distal end 52 of the spring 50 is received in the position slot 314. The second through holes 331 in the handle 33 are aligned with the fixing hole 324 of the operating portion 321. The fastener 60 passes through the second through holes 331 and the fixing hole 324 to fix the handle 33 to the rotating axle 32. The switch member 30 is located in the second mounting hole 21 of the second circuit board 20. The plurality of protrusion ribs 311 on the enclosure 31 grasp an inner surface of the second mounting hole 21. Therefore, the switch member 30 is mounted on the second circuit board 20. In an original state, the handle 33 compresses a top of the spring 50 slightly, and a bottom of the spring 50 abuts against a top surface of the first supporting portion 313.

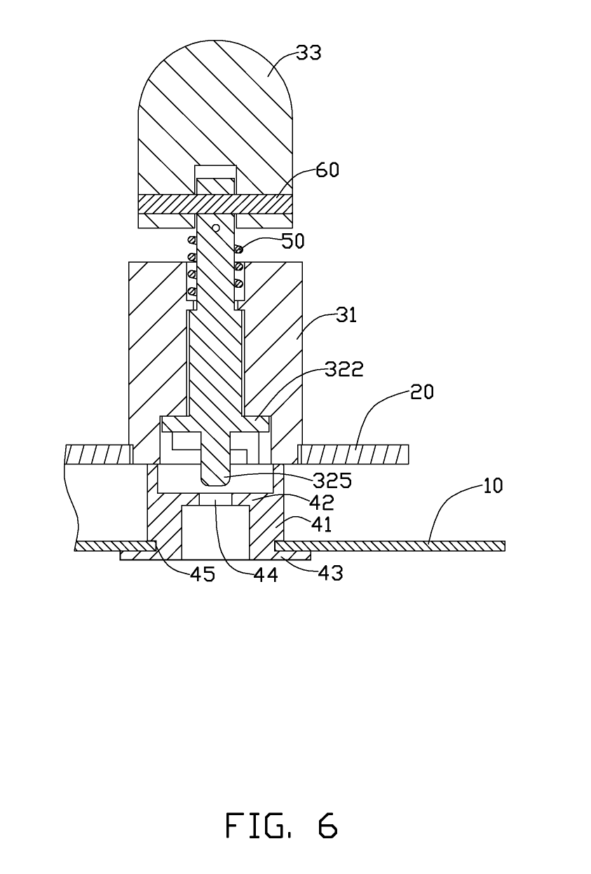

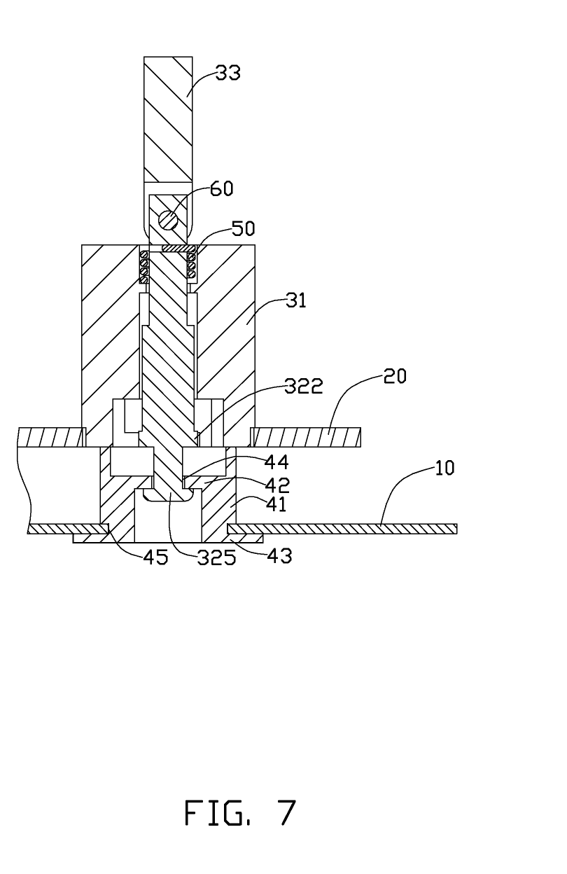

FIGS. 6 and 7 show that in operation, when the second circuit board 20 is attached to the first circuit board 10, the first mounting hole 11 of the first circuit board 10 is aligned with the second mounting hole 21 of the second circuit board 20. The second circuit board 20 and the switch member 30 are manually moved toward the first circuit board 10 and the position member 40. When the enclosure 31 of the switch member 30 resists against a top of the position member 40, the handle 33 is pressed toward the enclosure 31, compressing the spring 50. When the second engaging portion 325 is pushed through the first positioning hole 44 of the position member 40, the handle 33 is rotated clockwise 90 degrees. The handle is rotated until two ends of the second engaging portion 325 resist against a bottom surface of the top wall 42 and the resisting portions 317 abut against the ends of the first engaging portion 322 to stop the handle 33 from rotating. The first engaging portion 322 abuts against the two second supporting portions 316. The spring 50 decompresses slightly when the handle 33 is released.

To detach the second circuit board 20 from the first circuit board 10, the handle 33 is rotated counterclockwise 90 degrees. The first engaging portion 322 does not abut against the two second supporting portions 316. The top wall 42 does not resist against the two ends of the second engaging portion 325, and the handle 33 is lifted up until the second engaging portion 325 is lifted out of the first positioning hole 44. Therefore, the second circuit board 20 is detached from the first circuit board 10.

Even though numerous characteristics and advantages of the present disclosure have been set forth in the foregoing description, together with details of the structure and function of the disclosure, the disclosure is illustrative only, and changes may be made in detail, especially in the matters of shape, size, and the arrangement of parts within the principles of the disclosure to the full extent indicated by the broad general meaning of the terms in which the appended claims are expressed.

What is claimed is:

1. A mounting apparatus for fixing circuit boards comprising:
a position member configured to mount a first circuit board; the position member comprises a first positioning hole; and
a switch member configured to mount a second circuit board; the switch member comprises an enclosure and a rotating axle rotatably mounted in the enclosure; a spring positioned on the rotating axle; a first engaging portion and a second engaging portion extend from the rotating axle; two second supporting portions located on the enclosure; wherein the rotating axle resists against the spring and elastically deforms the spring; the second engaging portion passes through the first positioning hole and resists against the position member; and the second circuit board is attached to the first circuit board by the first engaging portion resisting against the two second supporting portions.

2. The mounting apparatus for fixing circuit boards of claim 1, wherein the position member comprises a sidewall, a top wall, and a bottom wall horizontally extending from the sidewall; the first positioning hole is defined in the top wall; a mounting groove is defined between the sidewall and the bottom wall; the position member is placed in a first mounting hole of the first circuit board; the mounting groove receives an inner surface of the first mounting hole; and the bottom wall resists against a bottom surface of the first circuit board.

3. The mounting apparatus for fixing circuit boards of claim 2, wherein a diameter of the sidewall is slightly greater than a diameter of the first mounting hole; and a width of the mounting groove is equal to a thickness of the first circuit board.

4. The mounting apparatus for fixing circuit boards of claim 1, wherein a plurality of protrusion ribs are formed on the enclosure; the switch member is placed in a second mounting hole of the second circuit board; and the plurality of protrusion ribs on the enclosure grasp an inner surface of the second mounting hole.

5. The mounting apparatus for fixing circuit boards of claim 4, wherein a diameter of the enclosure is slightly greater than a diameter of the second mounting hole.

6. The mounting apparatus for fixing circuit boards of claim 1, wherein the enclosure comprises a first through hole; a first supporting portion extends from an inside surface of the enclosure in the first through hole; a position slot is defined in the first supporting portion; the rotating axle comprises an operating portion; a second positioning hole is defined in the operating portion; the spring comprises a first distal end and a second distal end; the spring is located on the operating portion via the first through hole; the first distal end of the spring is received in the second positioning hole; and the second distal end of the spring is received in the position slot.

7. The mounting apparatus for fixing circuit boards of claim 6, wherein the first engaging portion and the second engaging portion horizontally extend from the operating portion; and a length of the first engaging portion is greater than a diameter of the first through hole.

8. The mounting apparatus for fixing circuit boards of claim 1, wherein the first engaging portion is perpendicular to the second engaging portion.

9. The mounting apparatus for fixing circuit boards of claim 1, wherein a cutout is defined at a bottom of the enclosure; the second supporting portion is located on each side of the first through hole in the cutout; a resisting portion is located on one side of each of the two second supporting portions; and the resisting portion resists against each of the first engaging portion.

10. A mounting apparatus for fixing circuit boards comprising:
a position member configured to mount a first circuit board; the position member comprises a first positioning hole; and
a switch member configured to mount a second circuit board; the switch member comprises an enclosure and a rotating axle rotatably mounted in the enclosure; a spring positioned on the rotating axle; a first engaging portion and a second engaging portion extend from the rotating axle; two second supporting portions located on the enclosure; a resisting portion located on one side of each second supporting portion; wherein the rotating axle resists against the spring and elastically deforms the spring; the second engaging portion passes through the first positioning hole and resists against the position member; the first engaging portion resists against the two second supporting portions; and the second circuit board is attached to the first circuit board by the resisting portions resisting against the first engaging portion.

11. The mounting apparatus for fixing circuit boards of claim 10, wherein the position member comprises a sidewall, a top wall, and a bottom wall horizontally extending from the sidewall; the first positioning hole is defined in the top wall; a mounting groove is defined between the sidewall and the bottom wall; the position member is placed in a first mounting hole of the first circuit board; the mounting groove receives an inner surface of the first mounting hole; and the bottom wall resists against a bottom surface of the first circuit board.

12. The mounting apparatus for fixing circuit boards of claim 11, wherein a diameter of the sidewall is slightly greater than a diameter of the first mounting hole; and a width of the mounting groove is equal to a thickness of the first circuit board.

13. The mounting apparatus for fixing circuit boards of claim 10, wherein a plurality of protrusion ribs are formed on the enclosure; the switch member is placed in a second mounting hole of the second circuit board; and the plurality of protrusion ribs on the enclosure grasp an inner surface of the second mounting hole.

14. The mounting apparatus for fixing circuit boards of claim 13, wherein a diameter of the enclosure is slightly greater than a diameter of the second mounting hole.

15. The mounting apparatus for fixing circuit boards of claim 10, wherein the enclosure comprises a first through hole; a first supporting portion extends from an inside surface of the enclosure in the first through hole; a position slot is defined in the first supporting portion; the rotating axle comprises an operating portion; a second positioning hole is defined in the operating portion; the spring comprises a first distal end and a second distal end; the spring is located on the operating portion via the first through hole; the first distal end of the spring is received in the second positioning hole; and the second distal end of the spring is received in the position slot.

16. The mounting apparatus for fixing circuit boards of claim 15, wherein the first engaging portion and the second engaging portion horizontally extend from the operating portion; and a length of the first engaging portion is greater than a diameter of the first through hole.

17. The mounting apparatus for fixing circuit boards of claim 10, wherein the first engaging portion is perpendicular to the second engaging portion.

18. The mounting apparatus for fixing circuit boards of claim 10, wherein a cutout is defined at a bottom of the enclosure; the second supporting portion is located on each side of the first through hole in the cutout; a resisting portion is located on one side of each of the second supporting portions; and the resisting portion resists against each of the first engaging portion.
